(19) United States
(12) Patent Application Publication
(10) Pub. No.: US 2024/0268134 A1
(43) Pub. Date: Aug. 8, 2024

(54) PHOTOELECTRIC CONVERSION ELEMENT

(71) Applicant: CANON KABUSHIKI KAISHA, Tokyo (JP)

(72) Inventor: TOMONA YAMAGUCHI, Tokyo (JP)

(21) Appl. No.: 18/413,993

(22) Filed: Jan. 16, 2024

(30) Foreign Application Priority Data
Jan. 20, 2023 (JP) 2023-007283
Nov. 21, 2023 (JP) 2023-197265

(51) Int. Cl. H10K 39/32; H10K 30/35; H10K 30/85; H10K 30/86; H10K 85/60

(52) U.S. Cl. CPC H10K 39/32; H10K 30/35; H10K 85/615; H10K 85/631; H10K 30/85; H10K 30/86

(57) ABSTRACT

The present disclosure discloses a photoelectric conversion element in which dark current is reduced, wherein the photoelectric conversion element includes a first electrode, a second electrode, and a photoelectric conversion layer disposed between the first electrode and the second electrode and including quantum dots, which include nanoparticles and a protective ligand, wherein the nanoparticles contain at least two elements selected from the group consisting of group 11 elements, group 12 elements, group 13 elements, group 14 elements, group 15 elements, and group 16 elements, and the protective ligand includes a cationic ligand and an anionic ligand, and the cationic ligand and the anionic ligand both have a molecular weight of 250 or less.

### BACKGROUND OF THE INVENTION

### Field of the Invention

The present disclosure relates to a photoelectric conversion element.

### Description of the Related Art

Quantum dots that have sensitivity in the long wavelength range tend to undergo oxidation and aggregation at their surfaces due to large particle size and large surface area. In a photoelectric conversion element that uses such quantum dots in a photosensitive layer, the amount of dark current increases due to formation of the electron trap level and narrowing of the bandgap. Most of photoelectric conversion films of typical light detecting apparatuses that use quantum dots are composed of quantum dots only, and thus the structure is prone to cause aggregation of quantum dots.

In the existing technical documents described below, quantum dots having surfaces protected with organic ligands and inorganic ligands are disclosed.

PCT Japanese Translation Patent Publication No. 2009-509129 (hereinafter referred to as PTL 1) discloses quantum dots having surfaces protected with an amine derivative, and a photoelectric conversion element that uses these quantum dots. However, the amine derivative is eliminated during the manufacture of the photoelectric conversion element and does not remain inside the element. The quantum dots in the photoelectric conversion layer are in an aggregated state, and the voltage applied to the photoelectric conversion element is prominently high.

Japanese Patent Laid-Open No. 2020-194844 (hereinafter referred to as PTL 2) discloses quantum dots having surfaces protected with an aromatic thiol derivative and a halogen element, and a photoelectric conversion element that uses these quantum dots. The wavelength range of this photoelectric conversion element is from visible light to 1200 nm, and the quantum dots used therein have a small particle size and thus are less prone to aggregate. However, when longer wavelength range quantum dots that have a larger particle size are to be used, quality deterioration caused by undesirable chemical reactions, such as aggregation at quantum dot surfaces, oxidation, and decomposition, is likely to occur.

The amine derivative in PTL 1 can only protect anions exposed in the surfaces of the quantum dots, and the thiol derivative and the halogen element in PTL 2 can only protect cations exposed in the surfaces of the quantum dots. Thus, in either case, the surfaces of the quantum dots are in a state in which elements not protected by the ligands are exposed. Thus, the issues with a photoelectric conversion element including a photoelectric conversion film that has sensitivity in the long wavelength range and that uses quantum dots are that the amount of dark current is large and the photoelectric conversion efficiency is low.

WO 2011/037042 (hereinafter referred to as PTL 3) discloses a cationic ligand and an anionic ligand. However, since the protective ligands are large, the quantum dot surfaces are not sufficiently covered, and the amount of the dark current is not sufficiently decreased.

### SUMMARY OF THE INVENTION

The present disclosure provides a photoelectric conversion element and a photoelectric conversion apparatus in which dark current is reduced.

A photoelectric conversion element of the present disclosure includes a first electrode, a second electrode, and a photoelectric conversion layer disposed between the first electrode and the second electrode. The photoelectric conversion layer includes quantum dots. The quantum dots include nanoparticles and a protective ligand. The nanoparticles contain at least two elements selected from the group consisting of group 11 elements, group 12 elements, group 13 elements, group 14 elements, group 15 elements, and group 16 elements. The protective ligand includes a cationic ligand and an anionic ligand, and the cationic ligand and the anionic ligand both have a molecular weight of 250 or less.

Further features of the present disclosure will become apparent from the following description of exemplary embodiments with reference to the attached drawings.

### BRIEF DESCRIPTION OF THE DRAWINGS

FIG. 1 is a schematic cross-sectional view of a photoelectric conversion apparatus according to an embodiment.

FIG. 2 is a schematic view illustrating one example of a surface structure of a quantum dot (QD) according to an embodiment.

FIG. 3 is a diagram illustrating one example of an imaging system that uses a photoelectric conversion element according to an embodiment of the present disclosure.

FIGS. 4A and 4B are diagrams illustrating structures of an imaging system and a moving body according to an embodiment of the present disclosure.

FIG. 5 is a graph illustrating one example of the external quantum efficiency of a photoelectric conversion element manufactured according to an embodiment.

### DESCRIPTION OF THE EMBODIMENTS

A photoelectric conversion element according to the present disclosure will now be described with reference to the drawings. Each of the embodiments merely illustrates one example of the present disclosure, and the numerical values, shapes, materials, constructional features, arrangement of the constructional features, connections, etc., do not limit the present disclosure. For example, in the embodiments, features such as transistors and semiconductor regions are described, but the conductivity type thereof is subject to modification as appropriate.

The features represented by the same reference signs in the drawings have identical or similar structures, and the description therefor is omitted to avoid redundancy. Furthermore, reference signs may be omitted for the features that can be understood as repeated patterns or identical structures.

### Photoelectric Conversion Element and Photoelectric Conversion Apparatus

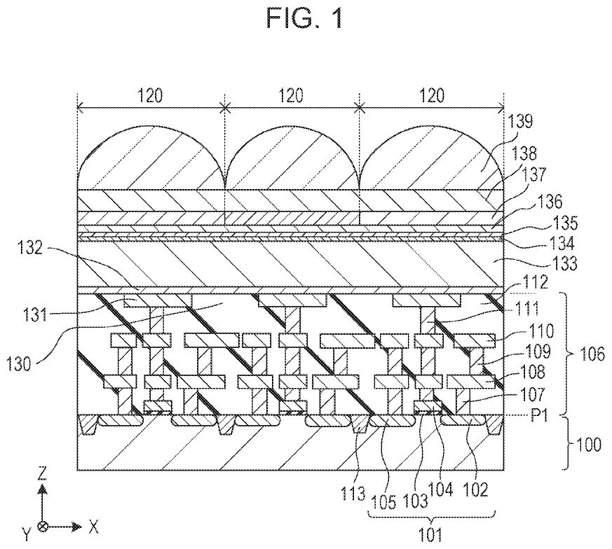

FIG. 1 is a schematic cross-sectional view of three unit cells 120 of a photoelectric conversion apparatus. FIG. 1 is a cross section taken at a plane that includes the Z direction, which is an upward direction, and the X direction. The unit cells 120 are also referred to as pixels or subpixels. The unit cells 120 have equivalent circuit arrangements and each have at least one photoelectric conversion element. In this embodiment, a structure in which each of the unit cells 120 has one photoelectric conversion element is described. The photoelectric conversion element is configurated by selecting, as appropriate, materials of a photoelectric conversion layer 133 described below. The circuit arrangement of the unit cell of the photoelectric conversion apparatus is set as appropriate. Next, the photoelectric conversion apparatus illustrated in FIG. 1 is described in detail.

### Substrate 100

In FIG. 1, a substrate 100 has a principal surface P1. The material for the substrate 100 may be glass, ceramic, or the like, and, in this embodiment, the substrate 100 is a semiconductor substrate composed of silicon single crystals. The substrate 100 includes a transistor 101 and an element isolation portion 113. The transistor 101 includes a source/drain region 102, a gate insulating film 103, a gate electrode 104, and a source/drain region 105. The gate electrode 104 is disposed on the principal surface P1. The gate insulating film 103 is positioned between the gate electrode 104 and the principal surface P1. The source/drain region 102 and the source/drain region 105 are inside the substrate 100.

### Wiring Structure 106

A wiring structure 106 is disposed on the principal surface P1 of the substrate 100. The wiring structure 106 includes a contact plug 107, a wiring layer 108, a via plug 109, a wiring layer 110, a via plug 111, and an insulating film 112. The insulating film 112 may be a multilayer film although this is not illustrated in detail in FIG. 1. These members may be composed of typical semiconductor materials.

### Electrodes (First Electrode 131 and Second Electrode 135)

The photoelectric conversion apparatus illustrated in FIG. 1 includes a first electrode 131 and a second electrode 135. The first electrode 131 may be an electron collecting electrode, a cathode, or a negative electrode. The second electrode 135 may be a hole collecting electrode, an anode, or a positive electrode. One of the first electrode 131 and the second electrode 135 may be an upper electrode, and the other a lower electrode. In FIG. 1, the first electrode 131 is a lower electrode, and the second electrode 135 is an upper electrode.

The second electrode 135 is disposed above the substrate 100. The second electrode 135 is continuous across the three unit cells 120. In this embodiment, the upper surface and the lower surface of the second electrode 135 are flat.

The first electrode 131 is disposed between the substrate 100 and the second electrode 135. At least one first electrode 131 is provided for each unit cell 120. In this embodiment, a structure in which each of the unit cells 120 has one first electrode 131 is described. An isolation region 130 is disposed between the first electrodes 131. The isolation region 130 may be the insulating film 112 of the wiring structure 106.

The first electrode 131 and the second electrode 135 can be electrodes composed of any desired conductive material. Examples of the material constituting the electrodes include metals such as platinum, gold, silver, aluminum, chromium, nickel, copper, titanium, and magnesium, and alloys and nitrides thereof, metal oxides such as indium oxide and tin oxide, and complex oxides thereof (for example, ITO and IZO).

Other examples of the material constituting the electrodes include conductive particles such as carbon black, fullerene, carbon nanotubes, and graphenes, and conductive hybrid materials in which such conductive particles are dispersed in a matrix such as a polymer binder. The materials constituting the electrodes may be used alone, or two or more materials may be used in any combination and any ratio. The photoelectric conversion element includes at least a pair of (two) electrodes, and the photoelectric conversion layer 133 is disposed between the pair of electrodes. Here, one of the pair of electrodes can be transparent. This is to transmit light to be absorbed by the photoelectric conversion layer 133.

The electrodes have functions of collecting electrons and holes generated inside the photoelectric conversion layer 133. Thus, among the materials constituting the electrodes described above, those constituent materials which are suitable for collecting electrons and holes can be used. Examples of the material for the second electrode 135 include materials suitable for collecting holes, for example, materials, such as Au and ITO, that have high work functions. Examples of the material for the first electrode 131 include materials suitable for collecting electrons, for example, materials, such as Al, titanium, and titanium nitride, that have low work functions. Among these, titanium or titanium nitride is preferably used. The thickness of the electrode may be any and is usually about 10 nm or more and 10 μm or less determined, as appropriate, by considering the materials used and the necessary conductivity, transparency, etc.

### Interface Layers (First Interface Layer 132 and Second Interface Layer 134)

The photoelectric conversion apparatus of the present disclosure can have a first interface layer 132 between the first electrode 131 and the photoelectric conversion layer 133. In addition, a second interface layer 134 can be disposed between the photoelectric conversion layer 133 and the second electrode 135. The photoelectric conversion apparatus of this embodiment includes the first interface layer 132 and the second interface layer 134. The first interface layer 132 may be a hole blocking interface layer or a hole blocking layer. The second interface layer 134 may be an electron blocking interface layer or an electron blocking layer.

The first interface layer 132 is disposed between the photoelectric conversion layer 133 and the first electrodes 131. FIG. 1 illustrates two interface layers that are spaced from each other. The second interface layer 134 is disposed between the photoelectric conversion layer 133 and the second electrode 135.

An interface layer is a layer for securing electrical insulation between an electrode and the photoelectric conversion layer 133 regarding one of carriers, that is, holes or electrons. Furthermore, an interface layer is also a layer for securing conduction between an electrode and the photoelectric conversion layer 133 regarding the other carrier. Thus, the interface layer can also be rephrased as a carrier injection blocking layer. In addition, an interface layer can function as an adhesion layer that can reduce film separation caused by poor wettability between the electrode and the photoelectric conversion layer 133. Thus, from the viewpoint of reducing the film separation, the interface layer can be formed on the entire surface in order to increase the contact area with the photoelectric conversion layer 133. Usually, a layer that blocks electrons and conducts only holes (electron blocking interface layer) can be formed for a hole collecting electrode (positive electrode), and a layer that blocks holes and conducts only electrons (hole blocking interface layer) can be formed for an electron collecting electrode (negative electrode).

The function of the first interface layer 132 (hole blocking interface layer) is to block holes separated from the photoelectric conversion layer 133 and transport electrons to the first electrode 131 (negative electrode). Thus, the material therefor may have such properties as high electron mobility, high electrical conductivity, low electron injection barrier with the negative electrode, and low electron injection barrier from the photoelectric conversion layer 133 to the hole blocking interface layer. There may be cases where light is coming in from the negative electrode side or where light reflected by the negative electrode side is to be effectively utilized, and the transmittance needs to be high in such cases. The presence of the first interface layer 132 can improve the photoelectric conversion efficiency EQE and decrease dark electrons.

Examples of the material for the hole blocking interface layer suitable from such a viewpoint include N-type semiconductor materials such as inorganic semiconductors, e.g., titanium oxide (TiO₂), zinc oxide (ZnO), indium-gallium-zinc oxide IGZO (InGaZnO₄), tungsten oxide (WO3), and molybdenum oxide (MoO₃). In particular, the electrical conductivity of oxide inorganic semiconductors can be easily changed by controlling the degree of oxidation through adjusting the film deposition conditions or the processes performed after the film deposition.

The material for the second interface layer 134 (electron blocking interface layer) can be a material that can efficiently transfer holes generated in the photoelectric conversion layer 133 to the second electrode 135 (positive electrode). This material may have such properties as high hole mobility, high electrical conductivity, low hole injection barrier with the positive electrode, and low hole injection barrier from the photoelectric conversion layer 133 to the electron blocking interface layer. In the case where light is to be brought into the photoelectric conversion layer 133 through the electron blocking interface layer, a highly transparent material can be used as the material for the electron blocking interface layer. In the case where visible light is to be brought into the photoelectric conversion layer 133, the transparent electron blocking interface layer material can have a transmittance of 60% or more and preferably 80% or more for the visible light to be transmitted. From this viewpoint, examples of the material for the electron blocking interface layer include inorganic semiconductors such as molybdenum oxide (MoO₃) and nickel oxide (NiO), and organic materials having triarylamine moieties such as a triphenylamine moiety, or fluorene moieties. The presence of the second interface layer 134 can improve the photoelectric conversion efficiency EQE and decrease dark electrons.

Examples of the organic materials having triarylamine moieties and fluorene moieties used in the second interface layer 134 include, but are not limited to, compounds H-1 to H-4 below.

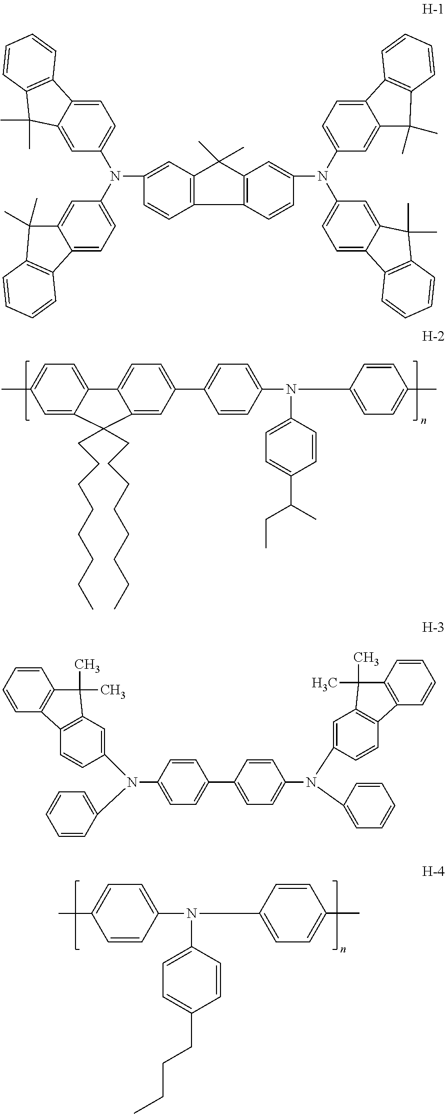

The film thickness of the interface layers, in particular, the film thickness of the second interface layer 134, is about 1 nm or more and about 100 nm or less. Injection of charges into the interface layer can be controlled by applying an electric field in the film thickness direction; however, charges can freely move in the horizontal direction with respect to the film thickness. When the interface layer as a film has a high electrical conductivity, leakage current and crosstalk could occur between unit cells.

### Photoelectric Conversion Layer 133

The photoelectric conversion layer 133 is disposed between the first electrode 131 and the second electrode 135. The photoelectric conversion layer 133 has quantum dots. The photoelectric conversion layer 133 performs photoelectric conversion, and the first electrode 131 can read out signals based on the charges generated by photoelectric conversion.

The material for the photoelectric conversion layer 133 may be an inorganic material or an organic material. For example, the photoelectric conversion layer can use quantum dots which are an assembly of nanoparticles of amorphous silicon, an organic semiconductor, or a compound semiconductor material. Examples of the organic semiconductor include fullerene (C60), coumarin 6 (C6), rhodamine 6G (R6G), quinacridone, phthalocyanines, and naphthalocyanines. In this embodiment, the photoelectric conversion layer 133 has quantum dots such as colloidal quantum dots that are nanoparticles of a compound semiconductor material, for example.

The quantum dots constituting the photoelectric conversion layer 133 have nanoparticles (having an average particle size of 0.5 nm or more and less than 100 nm). The nanoparticles contain at least two elements selected from the group consisting of group 11 (group I) elements, group 12 (group II) elements, group 13 (group III) elements, group 14 (group IV) elements, group 15 (group V) elements, and group 16 (group VI) elements. Examples of the materials for the nanoparticles include compound semiconductors composed of a combination of at least two elements selected from the group consisting of group 11 (group I) elements, group 12 (group II) elements, group 13 (group III) elements, group 14 (group IV) elements, group 15 (group V) elements, and group 16 (group VI) elements, for example. Specific examples thereof include semiconductor materials having relatively narrow bandgaps, such as PbS, PbSe, PbTe, InN, InP, InAs, InSb, InGaAs, CdS, CdSe, CdTe, CuInS, CuInSe, and CuInGaSe. These are also known as semiconductor quantum dots. The quantum dots are to contain at least one type out of these semiconductor quantum dot materials. The quantum dots may have a core-shell structure in which a semiconductor quantum dot material serving as a core is covered with a coating compound. Quantum dots having a size approximately the same as or smaller than the exciton Bohr radius specific to each semiconductor material exhibit a quantum size effect, and thus the desired bandgap, that is, light absorption wavelength, can be controlled by their size.

Among the aforementioned semiconductor quantum dot materials, PbS, PbSe, PbTe, InP, InAs, CdS, CdSe, and CdTe are preferable, and PbS or PbSe, which is composed of a group 14 (group IV) element and a group 16 (group VI) element, is more preferable as the semiconductor quantum dot material since photoelectric conversion is possible in a wide wavelength range of from the visible range to the SWIR range. The exciton Bohr radius of PbS is about 18 nm, and the average particle size of the quantum dots is preferably 2 nm or more and 15 nm or less and more preferably 4 nm or more and 15 nm or less. The particle size of the quantum dots is measured with a transmission electron microscope. When the average particle size of the quantum dots is 2 nm or more, crystal growth of the quantum dots can be easily controlled in synthesizing the quantum dots. By controlling the crystal growth of the quantum dots, the wavelength range for which the photoelectric conversion element has sensitivity can be selected.

The method for manufacturing the photoelectric conversion layer 133 composed of an assembly of nanoparticles as a quantum dot film is not particularly limited. The film thickness of the photoelectric conversion layer 133 is not particularly limited but is preferably 10 nm or more and more preferably 50 nm or more from the viewpoint of obtaining high light absorption characteristics. From the viewpoint of ease of manufacturing, the film thickness of the photoelectric conversion layer 133 can be 800 nm or less.

The quantum dot contains, as protective ligands for the surfaces of the nanoparticles, a cationic ligand and an anionic ligand. The protective ligands may be a combination of at least one cationic ligand and at least one anionic ligand, or at least one cationic and anionic ligand. The cationic ligand can be an aromatic compound having a cationic substituent, and the anionic ligand can be an aromatic compound having an anionic substituent.

Here, a cationic substituent refers to a substituent that has an ability to coordinate with an anion exposed in the nanoparticle surface and add protons. One example thereof is an amino group, but the cationic substituent is not limited to the amino group. Meanwhile, an anionic substituent refers to a substituent that has an ability to coordinate with a cation exposed in the nanoparticle surface and eliminate protons. Example thereof include, but are not limited to, a thiol group, a hydroxyl group, a carboxylic acid group, a sulfonic acid group, and a phosphonic acid group.

Cations and anions of constituent elements are present on the nanoparticle surfaces, and the existence ratio thereof is dependent on the element composition and the particle size of the nanoparticles. It is known that, when the surface area increases due to the increase in the particle size of the nanoparticles, different crystal planes become exposed in the surfaces, and the amounts of the exposed cations and anions and the defect rate increase or change. According to a monograph (Applied. Surface Science, 2018, vol. 457, 1-10), when the particle size of the PbS quantum dots is less than 4 nm, the surfaces of the quantum dots are (111) planes mainly composed of lead atoms; however, at a particle size of 4 nm or more, (100) planes in which sulfur atoms are exposed also mix in. The absorption wavelength of the PbS quantum dots having a particle size of 4 nm is about 1100 nm, and the influence of the exposed (100) planes increases in a SWIR region of a wavelength longer than this; thus, the quantum dot surfaces need further protection compared to the short-wavelength-range quantum dots.

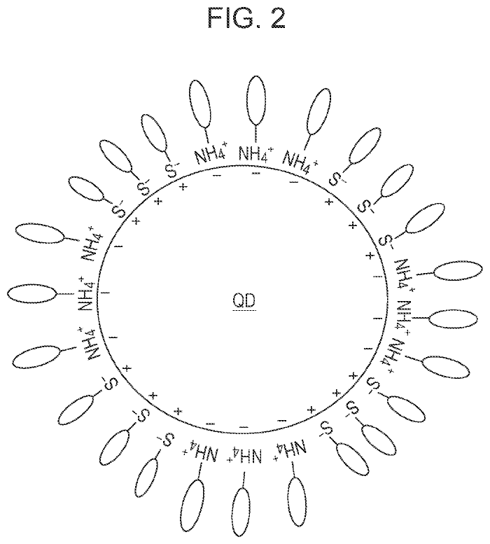

FIG. 2 is a schematic view illustrating one example of a surface structure of a quantum dot (QD) according to this embodiment. Both the cations and anions on the nanoparticle surface are protected by protective ligands.

In the existing example in PTL 1 described above, the anions on the nanoparticle surface are protected by a ligand that has an amino group as a cationic substituent. In PTL 2 described above, the cations on the nanoparticle surfaces are protected by a ligand that has a thiol group as an anionic substituent, and a halogen ligand, which is an inorganic anion. In either case, only the atoms having charges of one polarity present on the surfaces of the nanoparticles are protected, and the atoms that have charges of the opposite polarity remain exposed.

Examples of the protective ligand include compounds represented by formula (1) below.

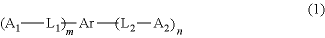

In formula (1), Ar is a six- or higher-membered ring aromatic hydrocarbon group or aromatic heterocyclic group. Ar may form a condensed polycycle or may include a substituent.

L₁ and L₂ are each a direct bond or a divalent linking group. The divalent linking group can be a straight-chain or branched-chain alkylene group, and some of the carbon and hydrogen atoms constituting the structure may be substituted with a heteroatom-containing substituent. The alkylene group can have 1 or more and 3 or less carbon atoms.

A₁ represents one of a hydroxyl group, a carboxylic acid group, a thiol group, a sulfonic acid group, a phosphonic acid group, and an amino group. A₁ may have a substituent.

A₂ represents one of an alkyl group, an alkoxy group, an aromatic hydrocarbon group, an aromatic heterocyclic group, a halogen, a halogenated alkyl group, a hydroxyl group, a carbonyl group, a carboxylic acid group, a thiol group, a sulfonic acid group, a phosphonic acid group, and an amino group. A₂ may have a substituent.

m represents an integer of 1 or more and 3 or less, and n represents an integer of 0 or more and 2 or less.

A compound containing a benzene ring such as benzenedithiol or benzenediamine has a boiling point exceeding 200° C., and thus less elimination decomposition and evaporation from the nanoparticle surfaces occur at a high temperature of 140° ° C. or higher, thereby improving the heat resistance of a quantum dot film.

There are two methods to select the protective ligands.

A first method is to select a total of at least two ligands, that is, to select at least one cationic ligand and at least one anionic ligand. When a cationic ligand or an anionic ligand is a compound having two or more coordination sites, the quantum dots can be rigidly bridged. Thus, the quantum dots can be arranged densely without aggregation, the efficiency of transporting charges generated in the photoelectric conversion film is increased, and the EQE is high.

Main examples of the cationic ligand include, but are not limited to, aniline, N-methylaniline, N,N-dimethylaniline, N-ethyl-N-methylaniline, 2-phenylethylamine, 1-naphthylamine, 2-naphthylamine, 2-aminobiphenyl, 3-aminobiphenyl, 4-aminobiphenyl, 2-aminopyridine, 3-aminopyridine, 4-aminopyridine, 1,2-phenylenediamine, 1,3-phenylenediamine, and 1,4-phenylenediamine. The cationic ligand may have a substituent. Particularly, benzenediamine derivatives such as 1,2-phenylenediamine, 1,3-phenylenediamine, and 1,4-phenylenediamine are preferable.

Main examples of the anionic ligand include, but are not limited to, benzenethiol, benzenemethanethiol, benzenemethanethiol, biphenyl-4-thiol, 2-naphthalenethiol, 2-mercaptopyridine, 3-mercaptopyridine, 4-mercaptopyridine, 1,2-benzenedithiol, 1,3-benzenedithiol, 1,4-benzenedithiol, 1,2-benzenedimethanethiol, 1,3-benzenedimethanethiol, 1,4-benzenedimethanethiol, biphenyl-4,4-dithiol, benzoic acid, terephthalic acid, isophthalic acid, biphenyl 4,4′-dicarboxylic acid, 2-mercaptobenzoic acid, 3-mercaptobenzoic acid, 4-mercaptobenzoic acid, 2-mercaptopyridine-3-carboxylic acid, 6-mercaptopyridine-3-carboxylic acid, benzenesulfonic acid, 1-naphthalenesulfonic acid, 2-naphthalenesulfonic acid, and phenylphosphonic acid. The anionic ligand may have a substituent. Particularly, benzenedithiol derivatives such as 1,2-benzenedithiol, 1,3-benzenedithiol, and 1,4-benzenedithiol are preferable.

The second selection method is to select at least one cationic and anionic ligand, specifically, a ligand in which a cationic coordination site and an anionic coordination site coexist in the same molecule. In such a case, the ligand exchange operation is performed just once for each applied photoelectric conversion layer, and thus the process can be streamlined.

Main examples of the ligand in which a cationic coordination site and an anionic coordination site coexist in the same molecule include, but are not limited to, 2-aminothiophenol, 3-aminothiophenol, 4-aminothiophenol, 4-aminopyridine-2-carboxylic acid, 5-aminopyridine-2-carboxylic acid, 6-aminopyridine-2-carboxylic acid, and 6-aminopyridine-3-carboxylic acid. The ligand in which a cationic coordination site and an anionic coordination site coexist in the same molecule may have a substituent. In particular, aminobenzenethiol derivatives such as 2-aminothiophenol, 3-aminothiophenol, and 4-aminothiophenol are preferable.

The quantum dots may have at least one halogen selected from the group consisting of iodine, chlorine, and bromine added to the surfaces of the nanoparticles. Here, the halogen may be added as an inorganic ligand in ligand exchange at the quantum dot surfaces, or the halogen contained as a counterion of an ammonium ion, which is a protonated cationic ligand, may remain on the quantum dot surfaces. The presence of these materials protects defects on the surfaces of the quantum dots, and, in particular, the heat resistance can be improved when used in combination with a protective ligand composed of an aromatic compound. For example, when heat resistance of 170° ° C. or higher is gained, it becomes possible to form an on-chip color filter or an on-chip micro lens, and thus color and high sensitivity can be achieved.

### Other Layers

In FIG. 1, an insulating layer 136, a color filter layer 137, a planarization layer 138, and a lens layer 139 are disposed along the Z direction on the second electrode 135 in this order. The insulating layer 136 can function as a protective layer or a sealing layer. The color filter layer 137 includes color filters corresponding to multiple colors. For example, one unit cell 120 includes one color filter. The planarization layer 138 is disposed on the color filter layer 137 and has a flat upper surface. The lens layer 139 includes multiple micro lenses. For example, one unit cell 120 includes one micro lens.

### Methods for Manufacturing Photoelectric Conversion Element and Photoelectric Conversion Apparatus

Methods for manufacturing a photoelectric conversion element and a photoelectric conversion apparatus according to an embodiment will now be described with reference to FIG. 1.

### Substrate 100

First, a step of preparing a substrate 100 on which a wiring structure 106 is formed is described. An element isolation portion 113 and a transistor 101 are formed in the substrate 100, which is a semiconductor substrate. The element isolation portion 113 has, for example, a shallow trench isolation (STI) structure. The transistor 101 is, for example, an N-type MOS transistor, and includes a gate electrode 104, a gate insulating film 103, a source/drain region 102, and a source/drain region 105. The source/drain regions 102 and 105 are made of N-type semiconductor regions.

### Wiring Structure 106

Next, a wiring structure 106 is formed on the substrate 100. The contact plug 107, the via plug 109, and the via plug 111 are composed of a metal, for example, a material selected from Al, Cu, W, Ti, TiN, etc., and may have a titanium-titanium nitride-tungsten multilayer structure in this embodiment. The wiring layer 108 and the wiring layer 110 are composed of a metal, for example, a material selected from Al, Cu, W, Ti, TiN, etc., and may each have a tantalum-copper multilayer structure in this embodiment. The insulating film 112 is, for example, made of a silicon oxide or silicon nitride film.

### First Electrode 131

Next, a first electrode 131 is formed on the via plug 111. The first electrode 131 is formed to have a thickness of about 10 nm or more and about 500 nm or less. After the first electrode 131 is formed, the insulating film 112 may be formed. In such a case, planarization processing is performed so that the insulating film 112 and the first electrode 131 have the same upper surface height. The planarization processing involves etching or chemical mechanical polishing (CMP). A typical semiconductor process can be applied to these manufacturing methods.

### First Interface Layer 132

Next, a film that forms a first interface layer 132 is formed on the insulating film 112 and the first electrode 131. The film that forms the first interface layer 132 is composed of the aforementioned material, and is, for example, deposited by a vapor deposition method or a sputtering method to a thickness of about 1 nm or more and about 100 nm or less. When the film thickness of the first interface layer 132 is small, the voltage applied to the photoelectric conversion layer 133 can be decreased. In contrast, when the film thickness of the first interface layer 132 is large, passing of holes by a tunneling effect can be decreased, and film defects such as pin holes can be avoided. For example, by setting the film thickness of the first interface layer 132 to be larger than the irregularities on the surface of the first electrode 131, defects in the first interface layer 132 can be decreased. Considering these viewpoints, the film thickness of the first interface layer 132 can be set as appropriate.

Here, an example in which titanium oxide (TiO₂) is used as the material for the first interface layer 132 is described. In one example, a TiO₂ film is formed to a desired thickness at a particular RF power, a particular argon gas flow rate, and a chamber pressure by using a sputtering apparatus and a TiO₂ target.

### Photoelectric Conversion Layer 133

Next, a photoelectric conversion layer 133 is formed. Specifically, quantum dots that include nanoparticles of a compound semiconductor or the like are deposited onto the entire surface of the substrate to form a photoelectric conversion layer 133. Here, an example in which lead sulfide (PbS) is used as quantum dots is described.

First, the quantum dots of lead sulfide (PbS) are synthesized as “oleic acid-protected quantum dots” in which oleic acid having a long molecular length serves as a ligand, and applied to the substrate. However, the inter-quantum-dot distance is large, the conductivity of the photocarriers generated by light irradiation is poor, and the photoelectric conversion function tends to be low. Thus, ligand exchange from oleic acid to a protective ligand, preferably a protective ligand having a shorter molecular length, can be performed.

A method for replacing the ligand by a protective ligand can involve introducing an anionic ligand first and then a cationic ligand. When the bonding force between the cationic ligand and the negative charge on the nanoparticle surface and the bonding force between the anionic ligand and the positive charge on the nanoparticle surface are compared, the former is weaker since the difference in electronegativity of between directly bonded atoms is smaller. Thus, the anionic ligand that more strongly bonds with the nanoparticle surface can be introduced first.

In order to assist adding protons to the cationic ligand, a weak organic acid, such as acetic acid, may be added to the ligand solution.

A quantum dot film of a desired thickness can be formed by again repeating formation of an oleic acid-protected quantum dot film, ligand exchange, and rinsing for removing the excess ligand on the quantum dot film (40 nm to 60 nm in thickness) after the ligand exchange.

### Second Interface Layer 134

Next, a film that forms a second interface layer 134 is formed on the photoelectric conversion layer 133. The film that forms the second interface layer 134 is composed of the aforementioned material, and is deposited by a vapor deposition method or a sputtering method to a thickness of about 1 nm or more and about 100 nm or less. When the film thickness of the second interface layer 134 is small, the voltage applied to the photoelectric conversion layer 133 can be decreased. In contrast, when the film thickness of the second interface layer 134 is large, passing of electrons by a tunneling effect can be decreased, and film defects such as pin holes can be avoided. For example, by setting the film thickness of the second interface layer 134 to be larger than the irregularities on the surface of the second electrode 135, defects in the second interface layer 134 can be decreased. Considering these points, the film thickness of the second interface layer 134 can be set as appropriate.

### Second Electrode 135

Next, a second electrode 135 is formed. To be more specific, ITO, IZO, ZnO, or the like is deposited on the second interface layer 134 to form a second electrode 135.

### Annealing

The formed device is annealed to improve the photoelectric conversion efficiency and improve carrier injection. The annealing temperature is determined by the heat resistance of the materials used in the layers and can be lower than the lowest glass transition temperature among the glass transition temperatures of the organic compounds used in the materials. In order to obtain sufficient durability for the temperatures that can be applied in these processes, the glass transition temperature of the organic material can be at least 100° C.

### Other Layers

Next, an insulating layer 136, a color filter layer 137, a planarization layer 138, and a lens layer 139 are sequentially formed. A typical method for manufacturing a semiconductor apparatus can be applied to these manufacturing methods.

### Examples of Usage of Photoelectric Conversion Element

### Photoelectric Conversion Apparatuses Such as Light Receiving Element and Image Sensor

A photoelectric conversion element according to one embodiment of the present disclosure may be used in a photoelectric conversion apparatus such as a light receiving element or an image sensor. A light receiving element includes a photoelectric conversion element, a readout circuit that reads out charges from the photoelectric conversion element, and a signal processing circuit that receives charges from the readout circuit and processes signals. An image sensor includes multiple pixels and a signal processing circuit connected to the pixels, in which the pixels include a photoelectric conversion element and a readout circuit connected to the photoelectric conversion element.

### Imaging Apparatus

A photoelectric conversion element according to one embodiment of the present disclosure may be used in an imaging apparatus. An imaging apparatus includes an optical system including multiple lenses and a light receiving element that receives light that has passed through the optical system, in which the light receiving element includes a photoelectric conversion element. The imaging apparatus may specifically be a digital still camera or a digital camcorder.

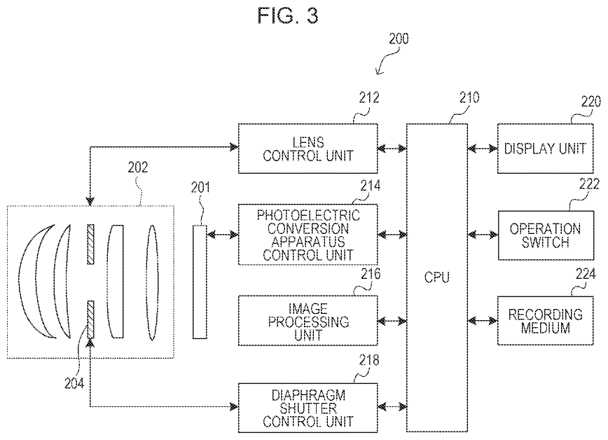

FIG. 3 is a diagram illustrating one example of an imaging system that uses a photoelectric conversion element according to an embodiment of the present disclosure. As illustrated in FIG. 3, an imaging system 200 includes a photoelectric conversion apparatus 201, an imaging optical system 202, a CPU 210, a lens control unit 212, a photoelectric conversion apparatus control unit 214, an image processing unit 216, a diaphragm shutter control unit 218, a display unit 220, an operation switch 222, and a recording medium 224.

The imaging optical system 202 is an optical system for forming an optical image of an object, and includes a lens group, a diaphragm 204, etc. The diaphragm 204 has a function of adjusting the light quantity during imaging by adjusting the aperture size thereof and a function of a shutter for adjusting the exposure time during still image photographing. The lens group and the diaphragm 204 are retained so as to be protractible and retractable along the optical axis direction, and variable power function (zoom function) and focal point adjusting function are realized by their coordinated movements. The imaging optical system 202 may be integrated with the imaging system or may be an imaging lens attachable to the imaging system.

The photoelectric conversion apparatus 201 is arranged so that the imaging plane is positioned in the image space of the imaging optical system 202. The photoelectric conversion apparatus 201 is a photoelectric conversion apparatus according to one embodiment of the present disclosure, and includes a CMOS sensor (pixel unit) and a peripheral circuit (peripheral circuit region) thereof. The photoelectric conversion apparatus 201 includes pixels having photoelectric conversion units arranged two dimensionally, and a color filter is installed to these pixels to thereby constitute a two-dimensional single-plate color sensor. The photoelectric conversion apparatus 201 photoelectrically converts the object image focused by the imaging optical system 202 to output an image signal or a focus detection signal.

The lens control unit 212 controls the protraction and retraction driving of the lens group of the imaging optical system 202 to perform variable power operation and focal point adjustment, and is constituted by circuits and processors configured to achieve such functions. The diaphragm shutter control unit 218 is for adjusting the imaging light quantity by changing the aperture size of the diaphragm 204 (by making the aperture value variable), and is constituted by circuits and processors configured to achieve such functions.

The CPU 210 is a controller inside the camera, is responsible for various controls for the camera body, and includes a computation unit, a ROM, a RAM, an A/D converter, a D/A converter, a communication interface circuit, etc. The CPU 210 controls the operations of various parts of the camera according to the computer program stored in the ROM or the like, and executes a series of imaging operations such as AF which includes detecting the focal point state (focus detection) of the imaging optical system 202, imaging, image processing, and recording. The CPU 210 doubles as a signal processor.

The photoelectric conversion control unit 214 is for controlling the operation of the photoelectric conversion apparatus 201, performing A/D conversion on the signal output from the photoelectric conversion apparatus 201, and sending the converted signal to the CPU 210, and is constituted by circuits and controllers configured to achieve these functions. The A/D conversion function may be performed by the photoelectric conversion apparatus 201. The image processing unit 216 is for generating an image signal by performing image processing, such as y conversion or color interpolation, on the A/D-converted signal, and is constituted by circuits and controllers configured to achieve these functions. The display unit 220 is a display apparatus such as a liquid crystal display (LCD), and displays information regarding the imaging mode of the camera, a preview image before imaging, a confirmation image after imaging, the focusing state in the focus detection, etc. The operation switch 222 is constituted by a power switch, a release (imaging trigger) switch, a zoom operation switch, an imaging mode selection switch, etc. The recording medium 224 is for recording an image already taken, and may be built in the imaging system or may be detachable, such as in the form of a memory card.

As such, a high-performance imaging system can be realized by this imaging system 200 in which the photoelectric conversion apparatus 201 according to an embodiment of the present disclosure is used.

### Moving Body

A photoelectric conversion element according to one embodiment of the present disclosure may be used in a moving body. The moving body includes a body in which an imaging apparatus is installed and a moving unit that moves the body. Specific examples thereof include automobiles, airplanes, ships, and drones. By installing the imaging apparatus in the moving body, the surrounding situations can be imaged, and the operation of the moving body can be supported. The body can be made of metal or carbon fibers. Polycarbonate can be used as the carbon fibers, for example. Examples of the moving unit include tires, magnetic levitation, and vaporizing and jetting a fuel.

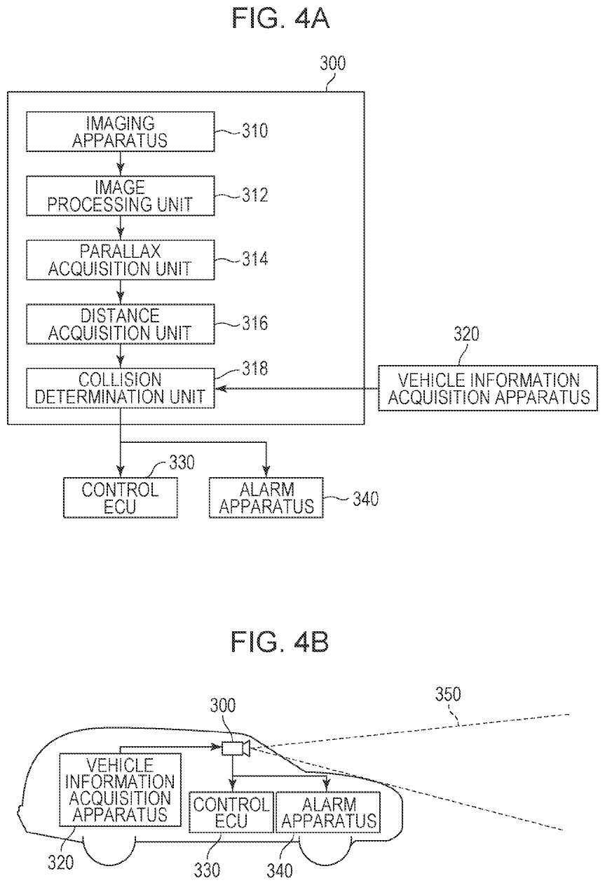

FIGS. 4A and 4B are diagrams illustrating structures of an imaging system and a moving body according to an embodiment.

FIG. 4A illustrates one example of an imaging system 300 relevant to an on-vehicle camera. The imaging system 300 includes an imaging apparatus 310. The imaging apparatus 310 is an imaging apparatus described in this embodiment. The imaging system 300 includes an image processing unit 312 that performs image-processing on multiple pieces of image data acquired by the imaging apparatus 310. In addition, the imaging system 300 includes a parallax acquisition unit 314 which is a processor that calculates the parallax (the phase difference in the parallax image) from multiple pieces of image data acquired by the imaging apparatus 310. The imaging system 300 further includes a distance acquisition unit 316 that is a processor that calculates the distance to the target object on the basis of the calculated parallax, and a collision determination unit 318 that is a processor that determined whether there is a possibility of collision on the basis of the calculated distance. Here, the parallax acquisition unit 314 and the distance acquisition unit 316 are one example of an information acquisition unit that acquires information such as distance the target object. In other words, the distance information is information about the parallax, the de-focusing amount, the distance to the target object, etc. The collision determination unit 318 may determine the collision possibility by using any one of these pieces of distance information. The aforementioned various processors may be realized by specially designed hardware or common hardware that performs computation on the basis of the software modules. In addition, these processors may be realized by field programmable gate arrays (FPGA), application specific integrated circuits (ASIC), etc., or by a combination of these.

The imaging system 300 is connected to a vehicle information acquisition apparatus 320 and can acquire vehicle information such as vehicle speed, yaw rate, and rudder angle. In addition, the imaging system 300 is connected to a control ECU 330, which is a controller that outputs a control signal that generates a braking force to a vehicle on the basis of the determination result made in the collision determination unit 318. In other words, the control ECU 330 is one example of a moving body control unit that controls the moving body on the basis of the distance information. The imaging system 300 is also connected to an alarm apparatus 340 that generates an alarm to a driver on the basis of the determination result made in the collision determination unit 318. For example, when the determination result of the collision determination unit 318 indicates a high collision possibility, the control ECU 330 performs vehicle control to avoid collision and reduce the damage by, for example, braking, deaccelerating, or suppressing the engine output. The alarm apparatus 340 sounds an alarm by making noise or the like, displays alarm information on the screen of a car navigation system or the like, or makes a seat belt or a steering vibrate to alarm the user.

In this embodiment, the surrounding of the vehicle, for example, the front or back of the vehicle, is imaged with the imaging system 300. FIG. 4B illustrates an imaging system 300 used to image the front of the vehicle (imaging range 350). The vehicle information acquisition apparatus 320 sends a command to activate the imaging system 300 and perform imaging. By using the imaging apparatus of this embodiment as the imaging apparatus 310, the ranging accuracy of the imaging system 300 of this embodiment can be improved.

In the description above, an example in which control is executed to avoid collision with other vehicles is described; alternatively, the present disclosure can also be applied to control that enables automated driving that involves tracking other vehicles and control that enables automated driving that involves staying in the lane. Furthermore, the imaging system can be applied not only to the vehicles such as automobiles, but to any moving body (transport appliance) such as a ship, an airplane, or an industrial robot. The moving apparatus in the moving body (transport appliance) is any of various moving mechanisms such as engines, motors, wheels, and propellers. In addition, the imaging system can be applied not only to the moving body but also to any appliance that utilizes a wide range of object recognition, such as the intelligent transport system (ITS).

### EXAMPLES

Hereinafter, the examples of the present disclosure are described, but these examples do not limit the scope of the present disclosure. In the examples, following photoelectric conversion elements that used PbS quantum dots, which are commonly used and have the widest range of particle size among the quantum dots, were manufactured, and the characteristics of the elements were evaluated; however, the composition is not limited to PbS, and quantum dots having other semiconductor compositions may be used. Note that these examples are presented to show the effect of decreasing the dark current by evaluating the characteristics of the elements that involve various combinations. Thus, the materials, film thickness, and layer structure of each of the layers in the elements described below are merely examples, and the present disclosure is not limited to the examples disclosed herein.

### Example 1

A photoelectric conversion element of Example 1 was formed by sequentially stacking, on a Si substrate, an electron collecting electrode (first electrode), a hole blocking layer (first interface layer), a photoelectric conversion layer, an electron blocking layer (second interface layer), and a hole collecting electrode (second electrode). The receiving light wavelength range was set to 450 nm to 1700 nm.

### (1) Manufacturing Photoelectric Conversion Element

First, a Si substrate in which a wiring layer and an insulating layer were stacked and in which contact holes that extended from the wiring layer were formed in the insulating layer at positions corresponding to the pixels for establishing conduction was prepared. The contact holes were drawn out to the ends of the substrate by wiring, and pads were formed. A TiN electrode was formed to overlap the contact holes, and subjected to patterning so as to form a TiN electrode (electron collecting electrode) having an area of 0.64 mm². Here, the film thickness of the TiN electrode was set to 60 nm.

An element was manufactured on the Si substrate on which the electron collecting electrode was formed by using the constituent materials and film thicknesses indicated in Table 1 in the aforementioned order. The manufactured element was annealed at 100° C. for an hour.

TABLE 1

| | | Film |
|---|---|---|
| | Constituent materials | thickness (nm) |
| Electron collecting electrode | TiN | 60 |
| Hole blocking layer | TiO₂ | 50 |
| Photoelectric conversion layer | Nanoparticles: PbS | 200 |
| | Cationic ligand: | |
| | 1,3-benzenediamine | |
| | Anionic ligand: | |
| | 1,3-benzenedithiol | |
| Electron blocking layer | MoO₃ | 15 |
| Hole collecting electrode | ITO | 40 |

Specific methods for preparing a hole blocking layer, a photoelectric conversion layer, an electron blocking layer, and a hole collecting electrode are as follows.

### Hole Blocking Layer (First Interface Layer)

A TiO₂ film having a thickness of 50 nm was formed by using a sputtering apparatus and a TiO₂ target under the conditions of a RF power of 500 W, 100 sccm argon gas, and a chamber pressure of 0.5 Pa.

### Photoelectric Conversion Layer

### Synthesis Step

Into a three-necked flask, 892 mg of lead oxide (PbO), 40 mL of octadecene, and 4 mL of oleic acid were charged, and the flask was set on an oil bath. The set temperature of the oil bath was 90° C., the inside of the flask was purged with nitrogen, and nitrogen was flowed at a flow rate of 0.5 L/min to prevent oxidation of the quantum dots during the reaction. The content was stirred for 30 minutes or longer until the solution changed color from light yellow at the time of charging to transparent. Separately, 20 mL of an octadecene solution of 1.9 mM bistrimethylsilyl sulfide, which was a sulfur source, was prepared in a syringe in a glove box having a nitrogen atmosphere. This sulfur source was rapidly added to the solution that had turned transparent in the three-necked flask. One minute after the addition, the three-necked flask was removed from the oil bath and naturally cooled for 2 hours to room temperature, and then a next purification step was performed. Here, the solution was black, and formation of lead sulfide (PbS) quantum dots having surfaces protected with oleic acid was confirmed.

### Purification Step

The octadecene dispersion liquid of the quantum dots obtained in the synthesis step was transferred from the three-necked flask to a centrifuge tube. Thereto, acetone, which was a polar solvent, was added so as to make the quantum dots difficult to be stably dispersed in octadecene, and then centrifugal separation was performed with a centrifugal separator to settle the quantum dots. The centrifugal separation condition was 17,000 rpm for 20 minutes. The centrifuge tube was taken out of the centrifugal separator, the supernatant transparent acetone was discarded, and then an apolar solvent, toluene, was added to the quantum dots that had settled at the bottom of the centrifuge tube. After the addition of toluene, the centrifuge tube was shaken to re-disperse the quantum dots in toluene. Acetone was added again to this toluene dispersion liquid, and the resulting mixture was centrifuged at 15,000 rpm for 5 minutes to settle. Settling by acetone and re-dispersing by toluene were repeated three times to purify the quantum dot dispersion liquid to obtain a toluene dispersion liquid of quantum dots.

### Coating Solution Preparation Step

Acetone was added to the toluene dispersion liquid of quantum dots obtained in the purification step, and the resulting mixture was centrifuged in the same manner to settle. Finally, the quantum dots re-dispersed in octane, not toluene, so that the concentration was 80 mg/mL were used as a quantum dot coating solution.

### Step of Forming Quantum Dot Film

First, 1 mL of the quantum dot coating solution described above was dropped onto a center of a substrate, and spin coating was performed under a spin coating condition of 2,500 rpm for 30 seconds. The quantum dot film after spin coating was an oleic acid-protected quantum dot film (an assembly of quantum dots protected with oleic acid having a long molecular length).

Next, ligand exchange from oleic acid to a protective ligand having a shorter molecular length was performed. Here, 1,3-benzenedithiol was used as the anionic ligand, and 1,3-benzenediamine was used as the cationic ligand. As the ligand solutions for the ligand exchange, a 3 mM 1,3-benzenedithiol solution in N,N-dimethylformamide and a 3 mM 1,3-benzenediamine solution in N,N-dimethylformamide were used.

The anionic ligand solution (20 mL) was applied to the entire surface of the oleic acid-protected quantum dot film, and ligand exchange reaction was carried out for 30 seconds. Subsequently, the substrate was spun at 2,000 rpm for 60 seconds to shake off the liquid to dry. After the ligand exchange, the film was rinsed with acetonitrile or methanol, which was a solvent that dissolves the ligands, to remove excessive ligands remaining on the film. The film was further rinsed with octane to remove oleic acid eliminated from the quantum dots, and as a result oleic acid in the oleic acid-protected quantum dot film was eliminated and replaced with particular ligands to obtain a 1,3-benzenedithiol-protected quantum dot film. Next, by the same method, 20 mL of the cationic ligand solution was used to introduce the cationic ligand, and rinsing for removing the excessive ligand was performed. Here, the film thickness of the 1,3-benzenedithiol- and 1,3-benzenediamine-protected quantum dot film after the ligand exchange was 40 nm or more and 60 nm or less.

A quantum dot film of a desired thickness was formed by again repeating formation of an oleic acid-protected quantum dot film, ligand exchange, and rinsing on this quantum dot film (40 nm to 60 nm in thickness) after the ligand exchange. In this example, the process is repeated four times to form a quantum dot film (200 nm in thickness) equivalent of four layers.

### Electron Blocking Layer (Second Interface Layer)

A MoO₃ film 15 nm in thickness was deposited by using a vapor deposition apparatus under a condition of a chamber pressure of 2.0×10⁻⁴ Pa.

### Hole Collecting Electrode (Second Electrode)

An ITO film 40 nm in thickness was deposited by using a sputtering apparatus and an ITO target under conditions of DC 400 V, 300 sccm argon gas, and a chamber pressure of 0.5 Pa.

### (2) Evaluation of Photoelectric Conversion Element

The manufactured element was used to measure the external quantum efficiency (EQE) and the number of dark electrons. The results are indicated in Table 2. A semiconductor parameter analyzer (4156B produced by Agilent Technologies) was used to apply voltage and measure the current. A high-precision spectrometer VC-250CA2 produced by BUNKOKEIKI CO., LTD., was used for light irradiation.

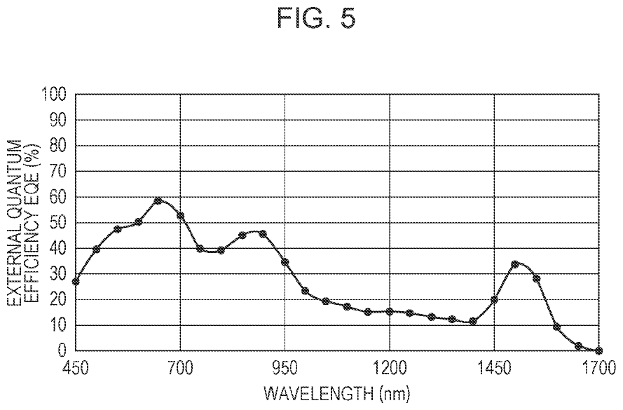

FIG. 5 is a graph illustrating the dependency of the external quantum efficiency of a photoelectric conversion element manufactured in this example on the wavelength.

The unit for the number of dark electrons (25° C.) is electrons/sec·μm².

The external quantum efficiency and the number of dark electrons are both evaluated at an application voltage of 2 V.

The evaluation standard for the number of dark electrons is as follows, where the rating of A or higher is considered satisfactory, and the rating of B or C is considered unsatisfactory.
AAA: Less than 15,000 electrons/sec·μm².
AA: 15,000 electrons/sec·μm² or more but less than 20,000 electrons/sec·μm².
A: 20,000 electrons/sec·μm² or more but less than 50,000 electrons/sec·μm².
B: 50,000 electrons/sec·μm² or more but less than 120,000 electrons/sec·μm².
C: 120,000 electrons/sec·μm² or more.

### Examples 2 to 5 and Comparative Examples 1 and 2

Photoelectric conversion elements were manufactured as in Example 1 except that protective ligands were changed as indicated in Table 2, and were evaluated. The results are indicated in Table 2.

TABLE 2

| | | Cationic ligand | | Anionic ligand | | Dark | |
|---|---|---|---|---|---|---|---|
| | | | Molecular | | Molecular | current | EQE (%) |
| | | Structure | weight | Structure | weight | (A/cm2) | @1500 nm |
| Examples | 1 | 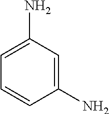 | 108 | 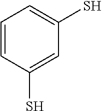 | 142 | AAA | 40 |
| | 2 | 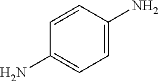 | 108 | 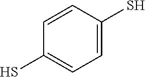 | 142 | AAA | 38 |
| | 3 | 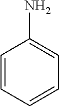 | 93 | 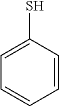 | 110 | AA | 35 |
| | 4 | 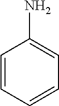 | 93 | 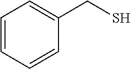 | 124 | A | 31 |
| | 5 | 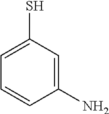 | 125 | 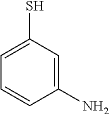 | 125 | AA | 32 |
| | 6 | 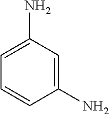 | 108 | 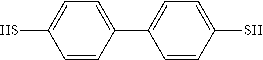 [SMILES: Sc1ccc(-c2ccc(S)cc2)cc1] | 218 | AA | 32 |
| | 7 | 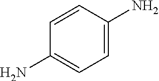 | 108 | 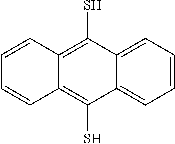 [SMILES: Sc1c2ccccc2c(S)c2ccccc12] | 242 | A | 25 |
| Comparative Examples | 1 | None | | 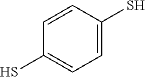 | 142 | B | 30 |
| | 2 | 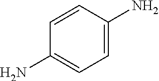 | 108 | None | | C | 22 |
| | 3 | 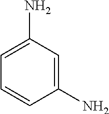 | 108 | 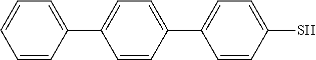 [SMILES: Sc1ccc(-c2ccc(-c3ccccc3)cc2)cc1] | 262 | B | 18 |
| | 4 | 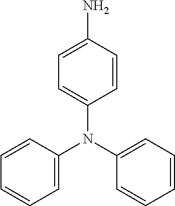 [SMILES: Nc1ccc(N(c2ccccc2)c2ccccc2)cc1] | 260 | 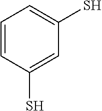 | 142 | C | 15 |

In Examples 1 to 4, one cationic ligand and one anionic ligand that satisfied formula (1) were contained as the protective ligands of the quantum dots. In Example 1 and 2, ligands having two coordination sites in one benzene ring and having a structure capable of rigidly bridging between the quantum dots were used. Thus, the quantum dots could be arranged densely without aggregation, the efficiency of transporting charges generated in the photoelectric conversion film was satisfactory, and the EQE was high. In Examples 3 and 4, one cationic ligand that had one coordination site in one benzene ring and one anionic ligand that had one coordination site in one benzene ring were mixed. The reason for high dark current and low EQE compared to Examples 1 and 2 is that ligands that did not have a structure of bridging between the adjacent quantum dots were used, and the evenness of the quantum dot dispersion in the photoelectric conversion film was poor.

In Example 5, a ligand that satisfied formula (1) and contained a cationic coordination site and an anionic coordination site coexisting in the same molecule was included as the protective ligand of the quantum dots. Since the ligand exchange is performed just once for each applied photoelectric conversion layer, the process can be streamlined. In such a case, the quantum dots disperse evenly, and the dark current is decreased. Meanwhile, the cation-to-anion ratio exposed on the quantum dot surfaces is not always 1:1, and as the ratio deviates from 1:1, the number of sites where bridging between adjacent quantum dots is possible decreases, and thus the effect of improving the EQE is less prominent.

In Comparative Examples 1 and 2, the protective ligand for the quantum dots was either a cationic ligand or an anionic ligand. Since positive charges or negative charges remain exposed on the quantum dot surfaces, aggregation and oxidation are prone to occur, and the dark current notably increases.

The present disclosure can provide a photoelectric conversion element and a photoelectric conversion apparatus in which dark current is reduced.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-007283, filed Jan. 20, 2023 and Japanese Patent Application No. 2023-197265, filed Nov. 21, 2023, which are hereby incorporated by reference herein in their entirety.

What is claimed is:

1. A photoelectric conversion element comprising:
a first electrode;
a second electrode; and
a photoelectric conversion layer disposed between the first electrode and the second electrode,
wherein the photoelectric conversion layer includes quantum dots,
the quantum dots include nanoparticles and a protective ligand,
the nanoparticles contain at least two elements selected from the group consisting of group 11 elements, group 12 elements, group 13 elements, group 14 elements, group 15 elements, and group 16 elements,
the protective ligand includes a cationic ligand and an anionic ligand, and
the cationic ligand and the anionic ligand both have a molecular weight of 250 or less.

2. The photoelectric conversion element according to claim 1, wherein the nanoparticles contain a group 14 element and a group 16 element.

3. The photoelectric conversion element according to claim 1, wherein the quantum dots have a particle size of 4 nm or more.

4. The photoelectric conversion element according to claim 1, wherein the protective ligand is a combination of at least one cationic ligand and at least one anionic ligand, or at least one cationic and anionic ligand.

5. The photoelectric conversion element according to claim 1, wherein the cationic ligand is an aromatic compound having a cationic substituent, and the anionic ligand is an aromatic compound having an anionic substituent.

6. The photoelectric conversion element according to claim 5, wherein the cationic substituent is an amino group, and the anionic substituent is a thiol group, a hydroxyl group, a carboxylic acid group, a sulfonic acid group, or a phosphonic acid group.

7. The photoelectric conversion element according to claim 1, wherein the protective ligand is represented by formula (1) below: 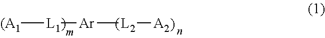
in formula (1), Ar is an aromatic hydrocarbon group or aromatic heterocyclic group that has a six- or higher-membered ring,
L₁ and L₂ are each a direct bond or a divalent linking group,
A₁ represents a hydroxyl group, a carboxylic acid group, a thiol group, a sulfonic acid group, a phosphonic acid group, or an amino group,
A₂ represents an alkyl group, an alkoxy group, an aromatic hydrocarbon group, an aromatic heterocyclic group, a halogen, a halogenated alkyl group, a hydroxyl group, a carbonyl group, a carboxylic acid group, a thiol group, a sulfonic acid group, a phosphonic acid group, or an amino group,
m represents an integer of 1 or more and 3 or less, and
n represents an integer of 0 or more and 2 or less.

8. The photoelectric conversion element according to claim 7, wherein Ar is monocyclic or bicyclic.

9. The photoelectric conversion element according to claim 1, wherein the cationic ligand is a benzenediamine derivative, and the anionic ligand is a benzenedithiol derivative.

10. The photoelectric conversion element according to claim 1, wherein the protective ligand is an aminobenzenethiol derivative.

11. The photoelectric conversion element according to claim 1, wherein the quantum dots further contain, as an inorganic ligand, at least one halogen element selected from the group consisting of iodine, chlorine, and bromine.

12. The photoelectric conversion element according to claim 1, wherein the first electrode contains titanium or titanium nitride.

13. The photoelectric conversion element according to claim 1, further comprising a first interface layer between the photoelectric conversion layer and the first electrode.

14. The photoelectric conversion element according to claim 12, wherein the first interface layer contains at least one selected from the group consisting of TiO₂, ZnO, InGaZnO₄, MoO₃, and WO3.

15. The photoelectric conversion element according to claim 1, further comprising a second interface layer between the photoelectric conversion layer and the second electrode.

16. The photoelectric conversion element according to claim 14, wherein the second interface layer contains at least one selected from the group consisting of MoO₃, NiO, and triarylamine moiety- or fluorene moiety-containing organic materials.

17. The photoelectric conversion element according to claim 1, further comprising, on the first electrode or the second electrode, at least one layer selected from the group consisting of a sealing layer, a lens layer, and a color filter layer.

18. A light receiving element comprising:
the photoelectric conversion element according to claim 1;
a readout circuit that reads out charges from the photoelectric conversion element; and
a signal processing circuit that receives charges from the readout circuit and processes signals.

19. An imaging apparatus comprising:
an optical system including a plurality of lenses; and
a light receiving element that receives light that has passed through the optical system,
wherein the light receiving element includes the photoelectric conversion element according to claim 1.

20. A moving body comprising:
a body in which an imaging apparatus is installed; and
a moving unit that moves the body,
wherein imaging apparatus is the imaging apparatus according to claim 19.
